(19) United States
(12) Patent Application Publication
(10) Pub. No.: US 2011/0165057 A1
(43) Pub. Date: Jul. 7, 2011

(54) PLASMA CVD DEVICE, DLC FILM, AND METHOD FOR DEPOSITING THIN FILM

(76) Inventors: Yuuji Honda, Nagareyama-shi (JP); Takeharu Kawabe, Nagareyama-shi (JP); Haruhito Hayakawa, Nagareyama-shi (JP); Koji Abe, Nagareyama-shi (JP)

(21) Appl. No.: 13/001,089

(22) PCT Filed: Jun. 30, 2009
(86) PCT No.: PCT/JP2009/061919

§ 371 Date: Mar. 8, 2011

(30) Foreign Application Priority Data
Jul. 1, 2008 (JP) 2008-172490

(51) Int. Cl. C01B 31/06; C23C 16/24; C23C 16/26; C23C 16/455; C23C 16/458; C23C 16/50

(52) U.S. Cl. 423/446; 118/723 E; 427/569; 427/577; 427/578

(57) ABSTRACT

To provide a plasma CVD device capable of increasing voltage V_{DC} that is a DC component generated at the electrode during high-frequency discharge in CVD deposition. The plasma CVD device according to the present invention includes a chamber 1, a holding electrode 2 disposed in the interior of the chamber and adapted for holding a substrate on which a film is to be deposited, a high frequency power supply 8 connected electrically with the holding electrode, a counter electrode 12 disposed opposite to the substrate on which a film is to be deposited held by the holding electrode and connected with an earth power supply or a float power supply, a raw material gas supply mechanism for supplying a raw material gas into a space 13 between the counter electrode and the holding electrode, and an evacuation mechanism for evacuating the interior of the chamber, wherein the surface area “a” of the holding electrode and the surface area “b” of the counter electrode satisfy a formula below,

b/a≧2.

### TECHNICAL FIELD

The present invention relates to a plasma CVD (chemical vapor deposition) device, a DLC film and a method for depositing a thin film.

### BACKGROUND ART

FIG. 2 is a constitutional view showing schematically a conventional plasma CVD device.

The plasma CVD device has a deposition chamber 101, and, in the upper part of the deposition chamber 101, a lid 102 is disposed. By closing the deposition chamber 101 with the lid 102, a deposition room 103 is formed in the deposition chamber 101.

In a lower part in the deposition room 103, a stage electrode 104, on which a substrate on which a film is to be deposited (not shown) is placed and fixed, is disposed. The stage electrode 104 is electrically connected with a high frequency power supply 106, and the stage electrode 104 also acts as an RF applying electrode. The surrounding area and lower part of the stage electrode 104 are shielded by an earth shield 105.

In the upper part in the deposition room 103, a gas shower electrode 107 is disposed in a position opposite and parallel to the stage electrode 104. These are a pair of parallel flat plate type electrodes. The surrounding area and the upper part of the gas shower electrode 107 are shielded by an earth shield 108. Furthermore, the gas shower electrode 107 is connected with the earth potential.

In the lower part of the gas shower electrode 107 (the upper surface side of the stage electrode), plural introduction ports (not shown) for introducing a shower-shaped raw material gas onto the surface side of the substrate on which a film is to be deposited are formed. Inside the gas shower electrode 107, a gas introduction route (not shown) is provided. One side of the gas introduction route is connected to the introduction port, and the other side of the gas introduction route is connected to a supply mechanism (not shown) of the raw material gas. Furthermore, the deposition chamber 101 is equipped with an exhaust port 110 for evacuating the inner part of the deposition room 103. The exhaust port 110 is connected to a vacuum pump (not shown).

Next, a deposition method using the plasma CVD device will be explained.

The substrate on which a film is to be deposited is inserted into the deposition room 103 of the plasma CVD device, and the substrate on which a film is to be deposited is placed on the stage electrode 104 in the deposition room.

Next, the substrate on which a film is to be deposited is fixed onto the stage electrode 104, and the deposition chamber 101 is closed with the lid 102 and is evacuated with the vacuum pump. Next, from the introduction port of the gas shower electrode 107, a shower-shaped raw material gas is introduced onto the surface side of the substrate on which a film is to be deposited in the deposition room 103. Then, the pressure, raw material gas flow rate etc. are controlled to prescribed values to set the interior of the deposition room to be an intended atmosphere, a high frequency (RF) is applied by a high frequency power supply 106, and a plasma is generated to subject the substrate on which a film is to be deposited to a deposition treatment.

### DISCLOSURE OF THE INVENTION

### Problems to be Solved by the Invention

Meanwhile, the conventional plasma CVD device involves such a problem that it cannot increase the voltage V_{DC} that is a DC component generated at the electrode during high-frequency discharge in CVD deposition, because the surface area of the gas shower electrode 107 is set to be approximately equal to that of the stage electrode 104.

In addition, in the conventional plasma CVD device, since parallel flat plate type electrodes composed of the stage electrode 104 and the gas shower electrode 107 are used, a plasma 111 generated in the space between the stage electrode 104 and the gas shower electrode 107 spreads laterally. As the result, there is such a problem that the density of the plasma 111 becomes low.

Furthermore, as the result of the spread of the plasma 111, there is such a problem that a CVD film adheres easily onto the inner wall of the deposition chamber 101 to thereby increase the load of the work of removing the adhered CVD film from the inner wall of the deposition chamber 101.

The present invention aims at solving at least one of above-described problems.

### Means for Solving the Problem

In order to solve the above problem, the plasma CVD device according to the present invention includes:

a chamber,

a holding electrode disposed in the chamber and adapted for holding a substrate on which a film is to be deposited,

a high frequency power supply connected electrically with the holding electrode,

a counter electrode disposed opposite to the substrate on which a film is to be deposited held by the holding electrode and connected with an earth power supply or a float power supply,

a raw material gas supply mechanism for supplying a raw material gas into a space between the counter electrode and the holding electrode, and

an evacuation mechanism for evacuating the interior of the chamber,

wherein a surface area “a” of the holding electrode and a surface area “b” of the counter electrode satisfy a formula below,

b/a≧2.

According to the plasma CVD device, it is possible to increase the voltage V_{DC} that is the DC (direct current) component generated at the electrode during the high-frequency discharge in the CVD deposition, by setting the surface area of the counter electrode connected with the earth power supply or the float power supply to be twice or more that of the holding electrode.

Furthermore, in the plasma CVD device according to the present invention, the counter electrode is preferably formed so as to cover the deposition surface of the substrate on which a film is to be deposited held by the holding electrode. This makes it possible to prevent the plasma generated in the space between the counter electrode and the holding electrode from spreading laterally, and, as the result, to suppress the lowering of the plasma density.

Moreover, in the plasma CVD device according to the present invention, the maximum gap between the counter electrode and the holding electrode at an opening part where the space on the inner side of the counter electrode is connected to the space on the outer side of the counter electrode is preferably 5 mm or less. This makes it possible to suppress the generation of abnormal discharge when the raw material gas in the CVD deposition passes the opening part. Accordingly, it is possible to confine the plasma in the space on the inner side of the counter electrode, and, as the result, to suppress the adhesion of a CVD film onto the inner wall of the chamber and the evacuation mechanism.

Furthermore, in the plasma CVD device according to the present invention, the frequency of the high frequency power supply is preferably from 100 kHz to 300 MHz, more preferably from 100 kHz to 60 MHz. When the frequency is less than 100 kHz, induction heating tends to occur, unpreferably.

In addition, the plasma CVD device according to the present invention can additionally have a high frequency power supply for applying high frequency power to the counter electrode and an earth power supply for applying earth potential to the holding electrode when removing the CVD film adhered onto the counter electrode. Meanwhile, a common power supply may be used as the high frequency power supply for applying high frequency power to the counter electrode and as the high frequency power supply for applying high frequency power to the holding electrode.

Moreover, the plasma CVD device according to the present invention is preferably further equipped with an earth shield disposed on the outer side of the counter electrode when the high frequency power is applied to the counter electrode. This makes it possible to increase the density of the plasma generated between the counter electrode and the holding electrode by applying the high frequency power to the counter electrode.

The plasma CVD device according to the present invention includes:

a chamber,

a holding electrode disposed in the chamber and adapted for holding a substrate on which a film is to be deposited,

a first earth power supply connected electrically with the holding electrode via a first switch,

a high frequency power supply connected electrically with the holding electrode via a second switch,

a counter electrode disposed opposite to the substrate on which a film is to be deposited held by the holding electrode and connected electrically with the high frequency power supply via the second switch,

a raw material gas supply mechanism for supplying a raw material gas into a space between the counter electrode and the holding electrode,

an evacuation mechanism for evacuating the interior of the chamber, and

a second earth power supply connected electrically with the counter electrode via a third switch,

wherein a surface area “a” of the holding electrode and a surface area “b” of the counter electrode satisfy a formula below,

b/a≧2.

In addition, the plasma CVD device according to the present invention can additionally have a float power supply connected electrically with the counter electrode via the third switch.

Furthermore, in the plasma CVD device according to the present invention, the counter electrode is preferably formed so as to cover the deposition surface of the substrate on which a film is to be deposited held by the holding electrode.

Moreover, in the plasma CVD device according to the present invention, the maximum gap between the counter electrode and the holding electrode at an opening part where the space on the inner side of the counter electrode is connected to the space on the outer side of the counter electrode is preferably 5 mm or less.

In addition, the DLC film according to the present invention is characterized in that it is deposited by using the aforementioned plasma CVD device.

The method for depositing a thin film according to the present invention is characterized in that, in a method for depositing a thin film using any of the aforementioned plasma CVD devices,

a substrate on which a film is to be deposited is held by the holding electrode, and

a thin film is formed on the surface of the substrate on which a film is to be deposited by putting the raw material gas into a plasma state by discharging between the substrate on which a film is to be deposited and the counter electrode in the chamber.

Furthermore, in the method for depositing a thin film according to the present invention, the thin film is also capable of containing carbon or silicon as a main component.

### BRIEF DESCRIPTION OF THE DRAWINGS

FIG. 1 is a cross-sectional view showing schematically a plasma CVD device according to an embodiment of the present invention.

FIG. 2 is a constitutional view showing schematically a conventional plasma CVD device.

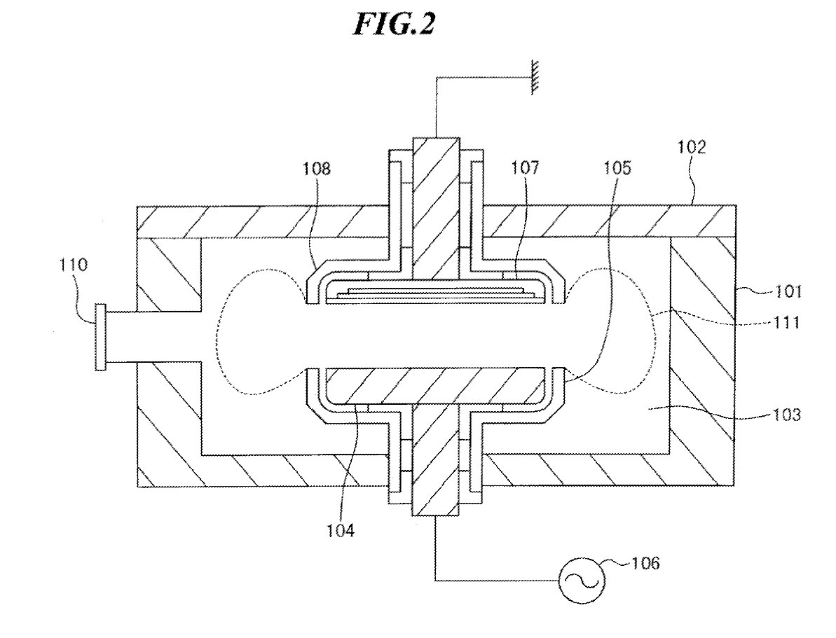

### BEST MODE FOR CARRYING OUT THE INVENTION

Hereinafter, the embodiment of the present invention will be explained with reference to the drawings.

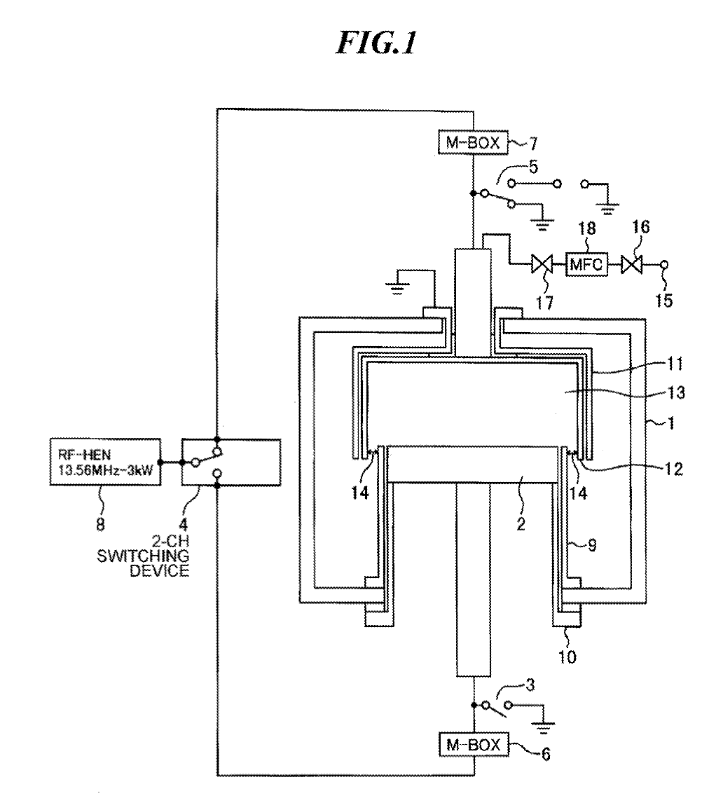

FIG. 1 is a cross-sectional view showing schematically a plasma CVD device according to an embodiment of the present invention.

The plasma CVD device has a deposition chamber 1, and, in the deposition chamber 1, a holding electrode 2 for holding a substrate on which a film is to be deposited (not shown) is disposed. The holding electrode 2 acts as a cathode in a CVD deposition. The surrounding area and lower part of the holding electrode 2 are shielded by earth shields 9 and 10.

In addition, in the deposition chamber 1, a counter electrode 12 is disposed so as to oppose the holding electrode 2. The counter electrode 12 is formed so as to cover the deposition surface of the substrate on which a film is to be deposited held by the holding electrode 2. In particular, the holding electrode 2 has, for example, a circular planar shape, and the counter electrode 12 has such an inner shape as an outer shape of a round column. Consequently, a space 13 between the counter electrode 12 and the holding electrode 2, that is, the space 13 on the inner side of the counter electrode 12 has a shape of an approximate cylinder. Meanwhile, in the present embodiment, the shape of the space 13 is set to be an approximate cylinder, but it can be set to be another shape.

Furthermore, the counter electrode 12 becomes an earth electrode in the CVD deposition to thereby act as an anode. The outer side of the counter electrode 12 is shielded by an earth shield 11.

Moreover, the counter electrode 12 is formed so that the surface area thereof is greater than that of the holding electrode 2. The surface area of the counter electrode 12 here means the surface area of the counter electrode 12 on the inner side, and the surface area of the holding electrode 2 means the surface area of the surface holding the substrate on which a film is to be deposited. When denoting the surface area of the holding electrode 2 by “a” and the surface area of the counter electrode 12 by “b,” they satisfy preferably formula (1) below, more preferably formula (2) below:

b/a≧2 (1)

b/a≧5 (2)

The opening part, through which the space 13 on the inner side of the counter electrode 12 is connected to the space on the outer side of the counter electrode 12, has a shape of a ring, and the maximum gap between the counter electrode 12 and the holding electrode 2 at the opening part is preferably 5 mm or less (more preferably 3 mm or less, furthermore preferably 2 mm or less). In the present embodiment, since the earth shield 9 is disposed between the counter electrode 12 and the holding electrode 2 at the opening part, the maximum gap between the counter electrode 12 and the holding electrode 2 corresponds to the maximum gap 14 between the counter electrode 12 and the earth shield 9, and the maximum gap 14 is preferably 5 mm or less (more preferably 3 mm or less, furthermore preferably 2 mm or less). The effect obtained by setting the gap to be 5 mm or less will be described later.

The holding electrode 2 is connected electrically with the earth power supply via the first switch 3. Further, the holding electrode 2 is connected electrically with a first matching box (M-BOX) 6, and the first matching box 6 is connected electrically with the high frequency power supply 8 via the second switch 4. That is, it is configured so that whether the holding electrode 2 is to be connected electrically with the high frequency power supply 8 or to the earth power supply can be switched by fist and second switches 3 and 4.

The counter electrode 12 is connected electrically with a second matching box (M-BOX) 7, and the second matching box 7 is connected electrically with the high frequency power supply 8 via the second switch 4. Further, the counter electrode 12 is connected electrically with the earth power supply or the float power supply via the third switch 5. That is, it is configured so that whether the counter electrode 12 is to be connected electrically with the high frequency power supply 8, or to the earth power supply, or to the float power supply can be switched by second and third switches 4 and 5.

The frequency of the high frequency power supply 8 is from 100 kHz to 300 MHz (preferably from 100 kHz to 60 MHz), and, in the embodiment, the high frequency power supply 8 of 13.56 MHz and 3 kW is used.

Furthermore, the plasma CVD device has an evacuation mechanism for evacuating the interior of the deposition chamber 1.

Moreover, the plasma CVD device has a raw material gas supply mechanism for supplying a raw material gas into the space 13 between the counter electrode 12 and the holding electrode 2. The raw material gas supply mechanism has a supply source 15 for supplying, for example, a raw material gas such as C₇H₈. The supply source 15 is connected with one end of a mass flow controller (MFC) 18 via a valve 16, and the other end of the mass flow controller 18 is connected with the counter electrode 12 via a valve 17. The counter electrode 12 is constituted so as to work as a gas shower electrode for introducing the raw material gas into the space 13 in a shower manner.

Next, a method of performing a CVD deposition treatment by using the plasma CVD device will be explained.

First, the substrate on which a film is to be deposited is held on the holding electrode 2. As the substrate on which a film is to be deposited, for example, a Si wafer, a plastic substrate, various kinds of electronic devices etc. can be used. The plastic substrate can be used, because the present device can deposit a film at a low temperature (for example, a temperature of 150° C. or less).

Next, the interior of the deposition chamber 1 is evacuated with the evacuation mechanism. Next, the supply source 15 supplies the raw material gas into the counter electrode 12 through the valve 16, the mass flow controller 18 and the valve 17, and, from the interior of the counter electrode 12, the raw material gas is introduced toward the space 13 over the holding electrode 2 in a shower manner. The raw material gas introduced flows to the outer side of the counter electrode 12 from the opening part having the maximum gap 14, and is evacuated by the evacuation mechanism. And, through the balance of the supply rate and the evacuation rate of the raw material gas, intended conditions such as a prescribed pressure and a prescribed flow rate of the raw material gas are set.

Meanwhile, as the raw material gas, various kinds of raw material gases may be used, and, for example, a hydrocarbon-based gas, a silicon compound gas, oxygen etc. can be used. As the silicon compound gas, the use of hexamethyldisilazane or hexamethyldisiloxane (they are also collectively referred to as HMDS), which is easy to be handled and capable of the deposition at a low temperature, is preferable.

Next, the earth power supply is connected with the counter electrode 12 by the third switch 5 to cause the counter electrode 12 to function as the earth electrode. Next, the high frequency power supply 8 is connected with the first matching box 6 by the second switch 4, and in a state where the earth power supply is not connected with the holding electrode 2 by the first switch 3, high frequency (RF) is applied to the holding electrode 2 by the high frequency power supply 8 via the second switch 4 and the first matching box 6. This causes the discharge between the substrate on which a film is to be deposited and the counter electrode 12 to generate plasma for the surface of the substrate on which a film is to be deposited and deposit a thin film on the substrate on which a film is to be deposited, by a plasma CVD method. After that, the substrate on which a film is to be deposited is taken out of the deposition chamber 1.

The thin film thus deposited is a film containing, for example, carbon or silicon as a main component. An example of a film containing carbon as a main component is a DLC film, and an example of a film containing silicon as a main component is a SiO₂ film. The raw material gas used when depositing the SiO₂ film contains HMDS and oxygen.

Meanwhile, in the above-described CVD deposition treatment method, a method, in which the earth potential is applied to the counter electrode 12 and high frequency is applied to the holding electrode 2 to deposit a thin film on the substrate on which a film is to be deposited, is used, but a method, in which a float potential is applied to the counter electrode 12 and high frequency is applied to the holding electrode 2 to deposit a thin film on the substrate on which a film is to be deposited, can also be used. The method of applying the earth potential to the counter electrode 12 can deposit a comparatively hard thin film, and, in contrast to this, the method of applying the float potential to the counter electrode 12 can deposit a comparatively soft thin film. When the float potential is to be applied to the counter electrode 12, the float power supply has only to be connected with the counter electrode 12 by the third switch 5.

Next, there will be explained an O₂ cleaning method of removing the CVD film adhered onto the inner side of the counter electrode 12 as a result of repeating the CVD deposition treatment.

First, the earth power supply is connected with the holding electrode 2 by the first switch 3 to cause the holding electrode 2 as the earth electrode. Next, a state, in which the high frequency power supply 8 is connected with the second matching box 7 by the second switch 4 and the counter electrode 12 is not connected with the earth power supply or the float power supply by the third switch 5, is constituted.

Next, the interior of the deposition chamber 1 is evacuated by the evacuation mechanism, and O₂ gas is introduced in a shower manner from the interior of the counter electrode 12 toward the space 13 over the holding electrode 2. The O₂ gas introduced flows to the outer side of the counter electrode 12 from the aforementioned opening part having the maximum gap 14, and is then evacuated by the evacuation mechanism.

Next, high frequency (RF) is applied to the counter electrode 12 by the high frequency power supply 8 via the second switch 4 and the second matching box 7. This generates plasma by means of O₂ in the space 13 on the inner side of the counter electrode 12 and, as the result, the inner side of the counter electrode 12 is subjected to the O₂ cleaning and the CVD film adhered onto the inner side of the counter electrode 12 is removed.

According to the embodiment, by setting the surface area of the counter electrode 12 to be twice or more that of the holding electrode 2, it is possible to increase the voltage V_{DC} that is the DC component generated at the electrode during high-frequency discharge in the CVD deposition, and, as the result, to increase the acceleration of ions. By increasing the acceleration of ions as described above, the generation of, for example, SiO₂ becomes easier.

In the present embodiment, the counter electrode 12 is formed so as to cover the deposition surface of the substrate on which a film is to be deposited, held by the holding electrode 2, and, therefore, the plasma generated in the space 13 between the counter electrode 12 and the holding electrode 2 does not extend laterally. This can suppress the lowering of the plasma density.

Furthermore, in the present embodiment, by shielding the outer side of the counter electrode 12 by the earth shield 11, it is possible to confine the O₂ plasma in the space 13 on the inner side of the counter electrode 12 when performing the O₂ cleaning. Accordingly, it is possible to increase the plasma density as compared with a case where no earth shield 11 is arranged, and to heighten the ashing rate of the CVD film. Consequently, it is possible to enhance the cleaning effect.

Moreover, in the present embodiment, the maximum gap between the counter electrode 12 and the holding electrode 2 at the opening part where the space 13 on the inner side of the counter electrode 12 is connected to the space on the outer side of the counter electrode 12 is set to be 5 mm or less (preferably 3 mm or less, and more preferably 2 mm or less). By making the gap of the opening part small as described above, the generation of abnormal discharge when the raw material gas in the CVD deposition passes the gap can be suppressed. Therefore, it is possible to confine the plasma in the space 13 on the inner side of the counter electrode 12, and, as the result, to thereby be able to suppress the adhesion of the CVD film onto the piping and valves of the evacuation mechanism positioned on the outer side of the counter electrode 12, the inner wall of the deposition chamber 1 etc.

Furthermore, as described above, the adhesion of the CVD film onto the inner wall of the deposition chamber 1 on the outer side of the counter electrode 12 is suppressed. Therefore, the CVD film adhered onto the inner wall of the counter electrode 12 has only to be capable of being removed, and, as the removal method, the aforementioned O₂ cleaning has only to be carried out. Accordingly, in the present embodiment, the cleaning is possible without breaking the vacuum of the deposition chamber 1 to thereby allow lightening remarkably the load of the work of removing the CVD film adhered onto the inner wall of the deposition chamber, different from conventional plasma CVD devices.

Meanwhile, the present invention is not limited to the above-described embodiment, but it can be practiced in a variously changed manner within the range that does not deviate from the gist of the present invention. For example, the high frequency power supply 8 can be changed to another plasma power supply, and examples of other plasma power supplies include power supplies for micro wave, power supplies for DC discharge, any of pulse-modulated high frequency power supplies, pulse-modulated power supplies for micro wave, pulse-modulated power supplies for DC discharge, etc.

Moreover, in the embodiment, the shape of the inner side of the counter electrode 12 is set so as to be the outer shape of a cylinder, but the shape of the inner side of the counter electrode 12 may be set to be a planar shape. In this case also, by satisfying the formula (1) above, the effect of the present invention can be obtained.

Furthermore, in the embodiment, as shown in FIG. 1, the configuration is such that the holding electrode 2 is arranged downward and the counter electrode 12 is arranged upward. But, other arrangement configurations can be adopted, and for example, an upside-down configuration of, for example, the holding electrode 2 being arranged upward and the counter electrode 12 being arranged downward, can also be adopted.

### EXAMPLES

### Example 1

An Example, in which the plasma CVD device shown in FIG. 1 is used and a CVD film is deposited on the substrate on which a film is to be deposited by the same method as that in the embodiment, will be explained.

(Deposition Condition)

Substrate on which a film is to be deposited: 6-inch Si wafer

Raw material gas: toluene (C₇H₈)

Flow rate of raw material gas: 4 cc/min

Pressure in deposition chamber: 0.13 Pa

RF frequency: 13.56 MHz

RF output: 900 W

Surface area “b” of counter electrode/surface area “a” of holding electrode: b/a=5.3

a=38013 mm², b=202274 mm²

(Deposition Result)

Deposited CVD film: DLC (Diamond Like Carbon) film

Thickness of CVD film: 100 nm

Hardness of DLC film: 2695 (average value of five points)

### (Measurement Method of Knoop Hardness)

Device: Microhardness Tester Model DMH-2, manufactured by Matsuzawa Seiki

Indenter tip: angle between opposite edges 172.5 °, 130° rhombic diamond square pyramid indenter tip

Weight: 5 g

Weighted time: 15 seconds

Measured points: arbitrary five points on sample

Example 1 showed that a DLC film having a very hard property and a high density was able to be deposited. Moreover, little DLC film adhered onto the piping and valve of the evacuation mechanism, the inner wall of the deposition chamber 1 etc. of the plasma CVD device.

### Example 2

An Example, in which the DLC film adhered onto the electrode surface of the holding electrode 2 is removed by the same O₂ cleaning method as that in the embodiment by using the plasma CVD device shown in FIG. 1, will be explained.

(Cleaning Condition)

Cleaning gas: O₂ gas

Flow rate of cleaning gas: 300 cc/min

Pressure in deposition chamber: 6.3 Pa

RF frequency: 13.56 MHz

RF output: 1200 W

surface area “b” of counter electrode/surface area “a” of holding electrode: b/a=5.3

a=38013 mm², b=202274 mm²

(Cleaning Result)

removal rate of DLC film: 1.125 nm/second

Example 2 showed that the DLC film having a thickness of 900 nm adhered onto the electrode surface of the holding electrode 2 was able to be entirely removed by performing the O₂ cleaning for 800 seconds, and that the removal rate was also large. Accordingly, the maintenance time was able to be shortened remarkably.

### Example 3

An Example, in which the DLC film adhered onto the inner wall of the counter electrode 12 is removed by the same O₂ cleaning method as that in the embodiment by using the plasma CVD device shown in FIG. 1, will be explained.

(Cleaning Condition)

Cleaning gas: O₂ gas

flow rate of cleaning gas: 300 cc/min

Pressure in deposition chamber: 6.3 Pa

RF frequency: 13.56 MHz

RF output: 1200 W

surface area “b” of counter electrode/surface area “a” of holding electrode: b/a=5.3

a=38013 mm², b=202274 mm²

(Cleaning Result)

Example 3 showed that the DLC film adhered onto the inner side of the counter electrode 12 was able to be entirely removed by performing the O₂ cleaning for 700 seconds, and that the removal rate was also large. Accordingly, the maintenance time was able to be shortened remarkably.

### Example 4

An Example, in which the DLC film is deposited on the substrate on which a film is to be deposited by the same method as that in the embodiment using the plasma CVD device shown in FIG. 1, will be explained.

(Deposition Condition)

Substrate on which a film is to be deposited: Si wafer

Raw material gas: HMDS-O, O₂

Flow rate of HMDS-O: 10 cc/min

Flow rate of O₂: 100 cc/min

Pressure in deposition chamber: 2 Pa

RF frequency: 13.56 MHz

RF output: 900 W

surface area “b” of counter electrode/surface area “a” of holding electrode: b/a=5.3

a=75476 mm², b=403776 mm²

(Deposition Result)

Deposited CVD film: SiO₂ film

Thickness of CVD film: 1500 nm

Knoop hardness of SiO₂ film (Hk): 1100

### (Measurement Method of Knoop Hardness)

Device: Microhardness Tester Model DMH-2, manufactured by Matsuzawa Seiki

Indenter tip: angle between opposite edges 172.5°, 130° rhombic diamond square pyramid indenter tip

Weight: 10 g

Weighted time: 15 seconds

Measured points: arbitrary five points on sample

Example 4 showed that, since the SiO₂ film had a Knoop hardness of 1100, a considerably dense film was formed.

### DESCRIPTION OF REFERENCE NUMERALS

1, 101: deposition chamber
2: holding electrode
3 to 5: first to third switch
6, 7: first and second matching box
8, 106: high frequency power supply
9, 10, 11, 105, 108: earth shield
12: counter electrode
13: space
14: maximum gap between counter electrode and earth shield
15: supply source
16, 17: valve
18: mass flow controller
102: lid
103: deposition room
104: stage electrode
107: gas shower electrode
110: exhaust port
111: plasma

1. A plasma CVD device comprising:
a chamber,
a holding electrode disposed in said chamber and adapted for holding a substrate on which a film is to be deposited,
a high frequency power supply connected electrically with said holding electrode,
a counter electrode disposed opposite to said substrate on which a film is to be deposited held by said holding electrode and connected with an earth power supply or a float power supply,
a raw material gas supply mechanism for supplying a raw material gas into a space between said counter electrode and said holding electrode, and
an evacuation mechanism for evacuating the interior of said chamber,
wherein
said counter electrode is formed so as to cover a deposition surface of said substrate on which a film is to be deposited held by said holding electrode,
the maximum gap between said counter electrode and said holding electrode at an opening part where a space on the inner side of said counter electrode is connected to a space on the outer side of said counter electrode is 5 mm or less, and
a surface area “a” of said holding electrode and a surface area “b” of said counter electrode satisfy a formula below,
b/a≧2.

2-3. (canceled)

4. The plasma CVD device according to claim 1,
wherein frequency of said high frequency power supply is 100 kHz to 300 MHz.

5. The plasma CVD device according to claim 1, further comprising a high frequency power supply for applying high frequency power to said counter electrode and an earth power supply for applying earth potential to said holding electrode when removing a CVD film adhered onto said counter electrode.

6. The plasma CVD device according to claim 5 further comprising an earth shield disposed on the outer side of said counter electrode when said high frequency power is applied to said counter electrode.

7. A plasma CVD device comprising:
a chamber,
a holding electrode disposed in said chamber and adapted for holding a substrate on which a film is to be deposited,
a first earth power supply connected electrically with said holding electrode via a first switch,
a high frequency power supply connected electrically with said holding electrode via a second switch,
a counter electrode disposed opposite to said substrate on which a film is to be deposited held by said holding electrode and connected electrically with said high frequency power supply via said second switch,
a raw material gas supply mechanism for supplying a raw material gas into a space between said counter electrode and said holding electrode,
an evacuation mechanism for evacuating an interior of said chamber, and
a second earth power supply connected electrically with said counter electrode via a third switch,
wherein a surface area “a” of said holding electrode and a surface area “b” of said counter electrode satisfy a formula below,
b/a≧2.

8. The plasma CVD device according to claim 7 further comprising a float power supply connected electrically with said counter electrode via said third switch.

9. The plasma CVD device according to claim 7, wherein said counter electrode is formed so as to cover a deposition surface of said substrate on which a film is to be deposited held by said holding electrode.

10. The plasma CVD device according to claim 9,
wherein the maximum gap between said counter electrode and said holding electrode at an opening part where a space on the inner side of said counter electrode is connected to a space on the outer side of said counter electrode is 5 mm or less.

11. A DLC film deposited using the plasma CVD device according to claim 1.

12. A method for depositing a thin film using the plasma CVD device according to claim 1, wherein:
a substrate on which a film is to be deposited is held by said holding electrode, and
a thin film is formed on the surface of said substrate on which a film is to be deposited by putting said raw material gas into a plasma state by discharging between said substrate on which a film is to be deposited and said counter electrode in said chamber.

13. The method for depositing a thin film according to claim 12,
wherein said thin film contains carbon or silicon as a main component.

14. A DLC film deposited using the plasma CVD device according to claim 7.

15. A method for depositing a thin film using the plasma CVD device according to claim 7, wherein:
a substrate on which a film is to be deposited is held by said holding electrode, and
a thin film is formed on the surface of said substrate on which a film is to be deposited by putting said raw material gas into a plasma state by discharging between said substrate on which a film is to be deposited and said counter electrode in said chamber.
